(19) United States
(12) Patent Application Publication
(10) Pub. No.: US 2013/0148062 A1
(43) Pub. Date: Jun. 13, 2013

(54) FILTER LAYER SUBSTRATE AND DISPLAY APPARATUS

(71) Applicants: Innocom Technology (SHENZHEN) Co. Ltd., Shenzhen City (CN); CHIMEI INNOLUX CORPORATION, Miao-Li County (TW)

(72) Inventors: Chih-Ming LIANG, Miao-Li County (TW); Kuo-Liang CHUANG, Miao-Li County (TW); Shu-Lan CHEN, Miao-Li County (TW)

(73) Assignees: CHIMEI INNOLUX CORPORATION, Miao-Li County (TW); INNOCOM TECHNOLOGY (SHENZHEN) CO., LTD, Shenzhen City (CN)

(21) Appl. No.: 13/684,887

(22) Filed: Nov. 26, 2012

(30) Foreign Application Priority Data
Dec. 7, 2011 (TW) 100145031

(51) Int. Cl. G02F 1/1335; H01L 33/08

(52) U.S. Cl. CPC G02F 1/133512; H01L 33/08
USPC 349/110; 257/88

(57) ABSTRACT

A filter layer substrate comprises a substrate, a black matrix layer, a filter layer, a protection layer, a first photoresist spacer, and a second photoresist spacer. The black matrix layer is disposed on the substrate. The filter layer covers the substrate and the black matrix layer. The protection layer is disposed on the filter layer. The first photoresist spacer is disposed on the protection layer corresponding to the black matrix layer. The second photoresist spacer is disposed on the protection layer corresponding to the black matrix layer. A bottom surface of the first photoresist spacer and a bottom surface of the second photoresist spacer have a height difference. A display apparatus containing the filter layer substrate is also disclosed. Accordingly, the liquid crystal margin of the LC filling can be enlarged, and the problems caused by the stress and the external collision or vibration can be avoided.

### CROSS REFERENCE TO RELATED APPLICATIONS

This Non-provisional application claims priority under 35 U.S.C. §119(a) on Patent Application No(s). 100145031 filed in Taiwan, Republic of China on Dec. 7, 2011, the entire contents of which are hereby incorporated by reference.

### BACKGROUND OF THE INVENTION

1. Field of Invention

The invention relates to a substrate and an apparatus and, in particular, to a filter layer substrate and a display apparatus.

2. Related Art

With the more mature liquid crystal display (LCD) technology, the LCD apparatus has been widely applied to various information products, such as notebooks, personal digital assistants (PDAs), smart phones, tablet computers, or other portable products. The LCD apparatus mainly includes an LCD panel, which includes a thin film transistor (TFT) substrate, a filter substrate, and a liquid crystal (LC) layer disposed between the TFT substrate and the filter substrate. Besides, a cell sealant and spacers are disposed to keep an interval between the TFT substrate and the filter substrate.

FIG. 1A is a sectional diagram of a conventional LCD panel 1. As shown in FIG. 1A, the LCD panel 1 includes a filter substrate 11, a TFT substrate 12, and an LC layer 13 disposed between the filter substrate 11 and the TFT substrate 12.

The filter substrate 11 includes a transparent substrate 111, a black matrix layer BM, a filter layer 112, and a protection layer 113. The black matrix layer BM, the filter layer 112, and the protection layer 113 are successively formed on the transparent substrate 111. The filter layer 112 has a red filter portion 112a, a green filter portion 112b, and a blue filter portion 112c. The spacers S1 and S2 are made of a photoresist material, and disposed corresponding to the black matrix layer BM and on the protection layer 113. The LCD panel 1 as shown in FIG. 1A is an IPS (in-plane switch) LCD panel for example, so the filter substrate 11 doesn't have a transparent conducting layer. However, if the LCD panel is another kind of panel, such as TN (twisted nematic) LCD panel, a transparent conducting layer will be disposed between the protection layer 113 and the spacers S1 and S2 for functioning as a common electrode. The TFT substrate 12 has a transparent substrate 121 and a TFT layer 122 which is disposed at a side of the transparent substrate 121.

Presently, LC filling is conducted mainly by the ODF (one drop fill) process. In this case, the liquid crystal margin of the LC filling will directly affect the yield and production of the ODF process.

FIG. 1B are sectional diagrams of the spacers S1 and S2 as shown in FIG. 1A, without showing the TFT substrate 12. In the conventional art as shown in FIG. 1B, the spacers S1 and S2 having different heights are disposed for enlarging the liquid crystal margin of the LC filling. The spacers S1 and S2 are disposed on the same plane, but their heights are different, so the top surfaces thereof have a height difference H. Thus, the liquid crystal margin of the LC filling can be enlarged. Accordingly, the ODF process can be improved in the yield and production.

### SUMMARY OF THE INVENTION

An objective of the invention is to provide a filter layer substrate and a display apparatus in which the bottom surfaces of two spacers have a height difference, thereby enlarging the liquid crystal margin of the LC filling and avoiding the stress problem caused by the following manufacturing processes, and the problem caused by the external collision or vibration.

To achieve the above objective, a filter layer substrate of the invention comprises a substrate, a black matrix layer, a filter layer, a protection layer, a first photoresist spacer, and a second photoresist spacer. The black matrix layer is disposed on the substrate. The filter layer covers the substrate and the black matrix layer. The protection layer is disposed on the filter layer. The first photoresist spacer is disposed on the protection layer corresponding to the black matrix layer. The second photoresist spacer is disposed on the protection layer corresponding to the black matrix layer. A bottom surface of the first photoresist spacer and a bottom surface of the second photoresist spacer have a height difference.

In one embodiment, a portion which is superimposed on the black matrix layer of the filter layer has at least one opening. The protection layer covers the filter layer and the black matrix layer. The second photoresist spacer is disposed corresponding to the opening.

In one embodiment, the first photoresist spacer and the second photoresist spacer are respectively corresponding to the two portions which have different heights of the protection layer.

In one embodiment, the thickness of the first photoresist spacer is the same as that of the second photoresist spacer

In one embodiment, the thickness of the first photoresist spacer is larger than that of the second photoresist spacer.

In one embodiment, the bottom surface of the first photoresist spacer means the surface connecting to the protection layer. The bottom surface of the second photoresist spacer means the surface connecting to the protection layer.

To achieve the above objective, a display apparatus of the invention includes a filter layer substrate and a driving substrate. The filter layer substrate comprises a substrate, a black matrix layer, a filter layer, a protection layer, a first photoresist spacer, and a second photoresist spacer. The black matrix layer is disposed on the substrate. The filter layer covers the substrate and the black matrix layer. The protection layer is disposed on the filter layer. The first photoresist spacer is disposed on the protection layer corresponding to the black matrix layer. The second photoresist spacer is disposed on the protection layer corresponding to the black matrix layer. A bottom surface of the first photoresist spacer and a bottom surface of the second photoresist spacer have a height difference. The driving substrate is disposed opposite to the filter layer substrate.

In one embodiment, a portion which is superimposed on the black matrix layer of the filter layer has at least one opening. The protection layer covers the filter layer and the black matrix layer. The second photoresist spacer is disposed corresponding to the opening.

In one embodiment, the first photoresist spacer and the second photoresist spacer are respectively corresponding to the two portions which have different heights of the protection layer.

In one embodiment, the thickness of the first photoresist spacer is the same as that of the second photoresist spacer.

In one embodiment, the thickness of the first photoresist spacer is larger than that of the second photoresist spacer.

In one embodiment, the bottom surface of the first photoresist spacer means the surface connecting to the protection layer. The bottom surface of the second photoresist spacer means the surface connecting to the protection layer.

In one embodiment, the display apparatus further includes a liquid crystal layer, which is disposed between the filter layer substrate and the driving substrate.

In one embodiment, the driving substrate is a thin film transistor (TFT) substrate or an organic light-emitting diode (OLED) substrate.

In one embodiment, the OLED substrate has a substrate and an OLED layer, which is disposed on a side facing the filter layer substrate of the substrate.

As mentioned above, in the filter layer substrate and the display apparatus of the invention, the first photoresist spacer is disposed on the protection layer corresponding to the black matrix layer, the second photoresist spacer is disposed on the protection layer corresponding to the black matrix layer, and the bottom surfaces of the first and second photoresist spacers have a height difference. Accordingly, the top surfaces of the first and second photoresist spacers have a height difference, which enlarges the liquid crystal margin of the LC filling, compared with the LCD panel having no height difference between the spacers, so as to improve the yield and production of the ODF process. Besides, the first and second photoresist spacers with a height difference between the top surfaces thereof can absorb the lateral stress generated by the following manufacturing processes, and prevent the light leakage or uneven contrast problem caused by the external collision or vibration.

### BRIEF DESCRIPTION OF THE DRAWINGS

The invention will become more fully understood from the detailed description and accompanying drawings, which are given for illustration only, and thus are not limitative of the present invention, and wherein:

FIG. 1A is a sectional diagram of a conventional LCD panel;

FIG. 1B are sectional diagrams of the spacers as shown in FIG. 1A;

FIG. 2A is a schematic top view of a filter layer substrate according to a preferred embodiment of the invention;

FIG. 2B are sectional diagrams taken along lines A-A and B-B in FIG. 2A;

FIGS. 3 to 5 are sectional diagrams of a pair of spacers of a filter layer substrate according to other aspects of the invention; and

FIG. 6 is a sectional diagram of a display apparatus according to a preferred embodiment of the invention.

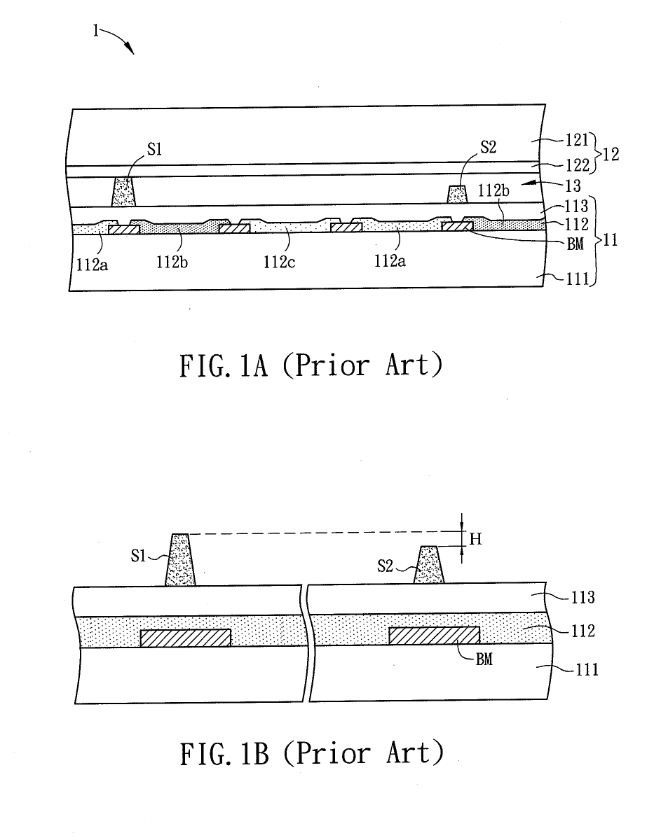

### DETAILED DESCRIPTION OF THE INVENTION

The present invention will be apparent from the following detailed description, which proceeds with reference to the accompanying drawings, wherein the same references relate to the same elements.

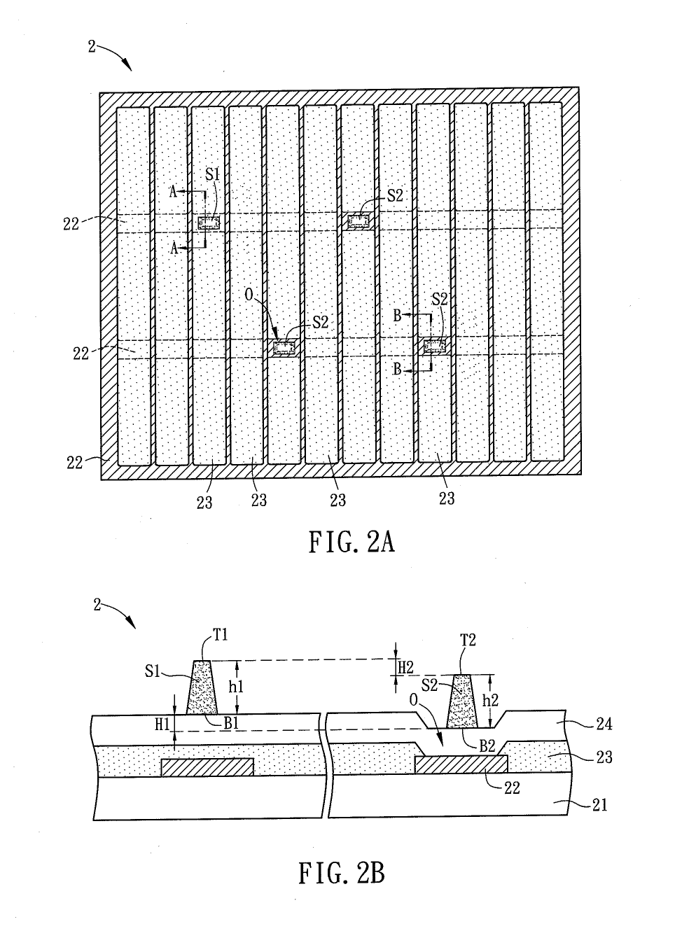

FIG. 2A is a schematic top view of a filter layer substrate 2 according to a preferred embodiment of the invention, and FIG. 2B are sectional diagrams taken along the lines A-A and B-B in FIG. 2A. As shown in FIGS. 2A and 2B, the filter layer substrate 2 includes a substrate 21, a black matrix layer 22, a filter layer 23, a protection layer 24, a first photoresist spacer S1, and a second photoresist spacer S2. For clearly showing the features of the invention, the substrate 21 and the protection layer 24 are omitted in FIG. 2A. The display apparatus of the embodiment is an IPS (in-plane switch) display apparatus for example, so the filter layer substrate 2 doesn't have a transparent conducting layer. However, if the display apparatus is of other kind, such as a TN (twisted nematic) display apparatus, a transparent conducting layer will be disposed between the protection layer 24 and the spacers S1 and S2 for serving as the common electrode.

The substrate 21 can be made of transparent material, and have a planar and even surface. The substrate 21 can be, for example, a glass substrate, a quartz substrate, or a plastic substrate.

The black matrix layer 22 is disposed on the substrate 21, and the filter layer 23 is disposed on the substrate 21 and the black matrix layer 22. The black matrix layer 22 is made of opaque material, such as metal, or resin, and the metal can be chromium, chromium oxide, or chromium nitride oxide, for example. Because the black matrix layer 22 is made of opaque material, the opaque areas and the transparent areas can be defined and formed on the transparent substrate 21. The filter layer 23 can include a red filter portion, a green filter portion, or a blue filter portion, which are all made of transparent material, such as pigments or dyes. The filter portions of various colors can be formed on the transparent substrate 21 and the black matrix layer 22 by the dyeing method, pigment dispersed method, printing method, dry film method, or electrodeposition method. In the embodiment, the filter layer 23 can be, but not limited to, a red filter layer, a green filter layer, a blue filter layer or their combinations.

The protection layer 24 is disposed covering the filter layer 23, and includes photoresist material or resin material. The protection layer 24 can be formed by the spin coating, slit and spin coating, or spinless coating. The protection layer 24 is disposed to make the surface of the filter layer 23 planarized and prevent the filter layer 23 from being affected by the following processes.

The first photoresist spacer S1 is disposed on the protection layer 24, corresponding to the black matrix layer 22. The second photoresist spacer S2 is disposed on the protection layer 24, corresponding to the black matrix layer 22. Besides, the bottom surface B1 of the first photoresist spacer S1 and the bottom surface B2 of the second photoresist spacer S2 have a height difference H1 based on a level plane. Here is an example of one first photoresist spacer S1 and three second photoresist spacers S2 as shown in FIG. 2A, but this is not for limiting the scope of the invention. The first photoresist spacer S1 and the second photoresist spacers S2 can be formed by using the sensitive photoresist material of a resin type, a silicate type, or a glass fiber type for example. The first photoresist spacer S1 and the second photoresist spacer S2 can be manufacturing by using the binary mask or the multi-tone mask including the gray-tone mask (GTM) or the half-tone mask (HTM). The first photoresist spacer S1 and the second photoresist spacer S2 can be a pillar-like body with a, for example, quadrangle, hexagonal, octagonal, circle, or elliptic cross-section. In the embodiment, the first photoresist spacer S1 and the second photoresist spacer S2 both have a trapezoid cross-section for example.

To be noted, the bottom surface B1 of the first photoresist spacer S1 means the surface connecting to the protection layer 24 of the first photoresist spacer S1. The bottom surface B2 of the second photoresist spacer S2 means the surface connecting to the protection layer 24 of the second photoresist spacer S2.

In the embodiment, a superimposed portion of the filter layer 23 superimposed on the black matrix layer 22 has at least one opening O. In other words, the filter layer 23 is separated or has a recess at the opening O. The protection layer 24 can totally cover the filter layer 23 and the black matrix layer 22, and the second photoresist spacer S2 is disposed corresponding to the opening O of the filter layer 23. In the embodiment, the portion which is corresponding to the second photoresist spacer S2 of the filter layer 23 has the opening O, but the portion which is corresponding to the first photoresist spacer S1 of the filter layer 23 doesn't have the opening O. The thickness h1 of the first photoresist spacer S1 is substantially the same as the thickness h2 of the second photoresist spacer S2, but the filter layer 23 doesn't have the opening O corresponding to the first photoresist spacer S1 while the filter layer 23 has the opening O corresponding to the second photoresist spacer S2. Therefore, the bottom surfaces B1 and B2 of the first photoresist spacer S1 and the second photoresist spacer S2 have a height difference H1, and the top surfaces T1 and T2 of the first photoresist spacer S1 and the second photoresist spacer S2 have a height difference H2, which is substantially equivalent to the height difference H1.

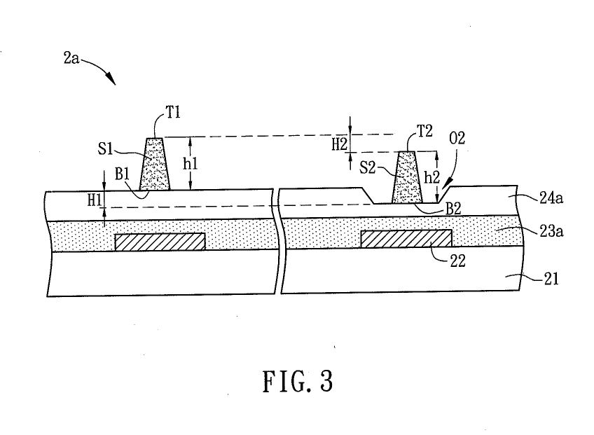

FIG. 3 is a sectional diagram of a pair of spacers S1 and S2 of a filter layer substrate 2a according to another aspect of the invention.

The main difference between the filter layer substrates 2a and 2 is that the filter layer 23a doesn't have openings respectively corresponding to the first photoresist spacer S1 and the second photoresist spacer S2. Besides, the second photoresist spacer S2 is disposed in a recess O2 of the protection layer 24a, so that the bottom surfaces B1 and B2 of the first photoresist spacer S1 and the second photoresist spacer S2 have a height difference H1. In the embodiment, the portion of the protection layer 24a where the first photoresist spacer S1 is disposed has a larger thickness than that of the portion of the protection layer 24a where the second photoresist spacer S2 is disposed, which can be caused by thinning the protection layer 24a by using the photo lithography process cooperating with the gray-tone mask or the half-tone mask. Accordingly, although the thicknesses h1 and h2 of the first photoresist spacer S1 and the second photoresist spacer S2 are substantially the same, the top surfaces T1 and T2 of them still have a height difference H2.

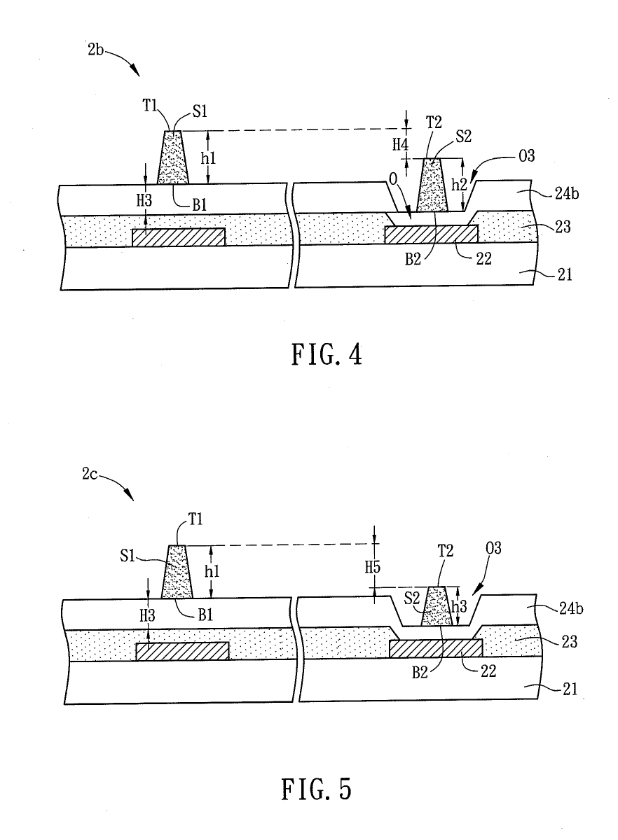

FIG. 4 is a sectional diagram of a pair of spacers S1 and S2 of a filter layer substrate 2b according to another aspect of the invention.

The main difference between the filter layer substrates 2b and 2 is that the protection layer 24b has a recess O3 which is disposed corresponding to the opening O of the filter layer 23, and the second photoresist spacer S2 is disposed in the recess O3. The thickness of the portion where the first photoresist spacer S1 is disposed of the protection layer 24b is larger than that of the portion where the second photoresist spacer S2 is disposed of the protection layer 24b. Accordingly, although the thicknesses h1 and h2 of the first photoresist spacer S1 and the second photoresist spacer S2 of the filter layer substrate 2b are substantially the same, the top surfaces T1 and T2 of the them still have a height difference H4, which is larger than the height difference H2 as shown in FIGS. 2 and 3. With the more enlarged height difference H4 between the photoresist spacers S1 and S2, the liquid crystal margin of the LC filling can be increased to improve the yield and production of the ODF process. Besides, the more enlarged height difference H4 can resist the lateral stress generated by the following film attaching process, and also prevent the light leakage or uneven contrast problem caused by the external collision or vibration.

FIG. 5 is a sectional diagram of a pair of spacers S1 and S2 of a filter layer substrate 2c according to another aspect of the invention.

The main difference between the filter layer substrates 2c and 2b is that the thickness h1 of the first photoresist spacer S1 is larger than the thickness h3 of the second photoresist spacer S2, so that a more enlarged height difference H5 (larger than the height difference H4) is formed between the top surfaces T1 and T2 of the photoresist spacers S1 and S2.

To be noted, the feature of the first and second photoresist spacers S1 and S2 with different heights can also be applied to the filter layer substrates 2 and 2a as shown in FIGS. 2 and 3, also leading to more enlarged height difference between the first and second photoresist spacers S1 and S2.

The technical features of the other elements of the filter layer substrates 2a, 2b, and 2c can be perceived by referring to the filter layer substrate 2, so the detailed descriptions are omitted here.

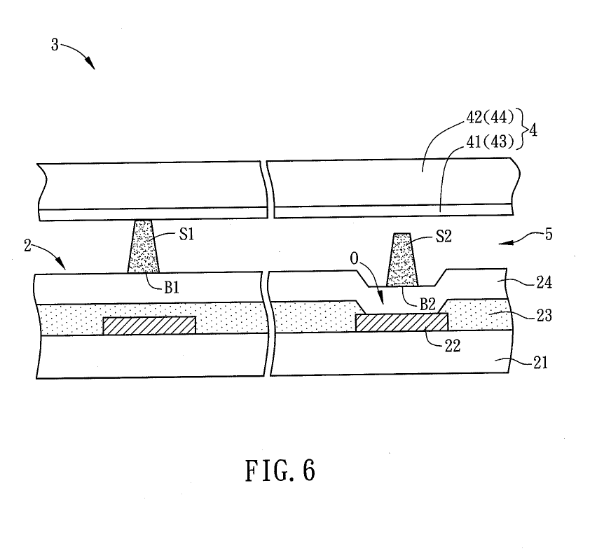

FIG. 6 is a sectional diagram of a display apparatus 3 according to a preferred embodiment of the invention.

The display apparatus 3 includes a filter layer substrate 2 and a driving substrate 4 disposed opposite to the filter layer substrate 2. The filter layer substrate 2 includes a transparent substrate 21, a black matrix layer 22, a filter layer 23, a protection layer 24, a first photoresist spacer S1, and a second photoresist spacer S2. The filter layer substrate 2 can have the technical features the same as those of the above embodiment, such as the filter layer substrate 2, 2a, 2b, or 2c, so the detailed descriptions are omitted here.

If the display apparatus 3 is an LCD apparatus, the driving substrate 4 can be a TFT substrate, which has a TFT matrix 41 and a transparent substrate 42. The TFT matrix 41 is disposed on a side of the transparent substrate 42 which is facing the filter layer substrate 2. Besides, the display apparatus 3 can further include a liquid crystal layer 5 which is disposed between the filter layer substrate 2 and the driving substrate 4.

Besides, if the display apparatus 3 is an organic light-emitting diode (OLED) display apparatus, the driving substrate 4 can be an OLED substrate, which includes a substrate 43 and an OLED layer 44. The OLED layer 44 is disposed on a side of the substrate 43 which is facing the filter layer substrate 2.

In summary, in the filter layer substrate and the display apparatus of the invention, the first photoresist spacer is disposed on the protection layer corresponding to the black matrix layer, the second photoresist spacer is disposed on the protection layer corresponding to the black matrix layer, and the bottom surfaces of the first and second photoresist spacers have a height difference. Accordingly, the top surfaces of the first photoresist spacer and the second photoresist spacer have a height difference, which enlarges the liquid crystal margin of the LC filling, compared with the LCD panel having no height difference between the spacers, so as to improve the yield and production of the ODF process. Besides, the first and second photoresist spacers with a height difference between the top surfaces thereof can absorb the lateral stress generated by the following manufacturing processes, and prevent the light leakage or uneven contrast problem caused by the external collision or vibration.

Although the invention has been described with reference to specific embodiments, this description is not meant to be construed in a limiting sense. Various modifications of the disclosed embodiments, as well as alternative embodiments, will be apparent to persons skilled in the art. It is, therefore, contemplated that the appended claims will cover all modifications that fall within the true scope of the invention.

What is claimed is:

1. A display apparatus, comprising:
a filter layer substrate comprising:
a substrate;
a black matrix layer disposed on the substrate;
a filter layer covering the substrate and the black matrix layer;
a protection layer disposed on the filter layer;
a first photoresist spacer disposed on the protection layer and corresponding to the black matrix layer; and
a second photoresist spacer disposed on the protection layer and corresponding to the black matrix layer, wherein a bottom surface of the first photoresist spacer and a bottom surface of the second photoresist spacer have a height difference.

2. The display apparatus as recited in claim 1, wherein the filter layer has at least one opening for exposing a surface of the black matrix layer, the protection layer covers the filter layer and the black matrix layer and has a recess corresponding to the opening, and the second photoresist spacer is disposed in the recess.

3. The display apparatus as recited in claim 1, wherein the thickness of the first photoresist spacer is the same as that of the second photoresist spacer, or the thickness of the first photoresist spacer is larger than that of the second photoresist spacer.

4. The display apparatus as recited in claim 1, wherein the protection layer has a recess, and the second photoresist spacer is disposed in the recess.

5. The display apparatus as recited in claim 4, wherein the filter layer has at least one opening, the protection layer has a second recess which is disposed corresponding to the opening, and the second photoresist spacer is disposed in the second recess.

6. The display apparatus as recited in claim 4, wherein the thickness of the first photoresist spacer is the same as that of the second photoresist spacer, or the height of the first photoresist spacer is larger than that of the second photoresist spacer.

7. The display apparatus as recited in claim 1, wherein the bottom surface of the first photoresist spacer means the surface connecting to the protection layer of the first photoresist spacer, and the bottom surface of the second photoresist spacer means the surface connecting to the protection layer of the second photoresist spacer.

8. The display apparatus as recited in claim 1, further comprising:
a driving substrate disposed opposite to the filter layer substrate; and
a liquid crystal layer disposed between the filter layer substrate and the driving substrate.

9. The display apparatus as recited in claim 8, wherein the driving substrate is a thin film transistor (TFT) substrate or an organic light-emitting diode (OLED) substrate.
